(19) United States
(12) Patent Application Publication
(10) Pub. No.: US 2008/0265425 A1
(43) Pub. Date: Oct. 30, 2008

(54) Semiconductor Device and Method for Manufacturing the Same

(76) Inventors: Sang Hee Lee, Eumseong-goon (KR); Gab Hwan Cho, Echeon-si (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/842,562

(22) Filed: Aug. 21, 2007

(30) Foreign Application Priority Data
Apr. 27, 2007 (KR) 10-2007-0041387

(51) Int. Cl. H01L 21/4763; H01L 23/48

(52) U.S. Cl. 257/773; 438/618; 257/E21.495; 257/E23.01

(57) ABSTRACT

A semiconductor device according to an embodiment can include a first group of dummy patterns and a second group of dummy patterns spaced apart from the first group of dummy patterns by a second spacing. The first group of dummy patterns can include a plurality of first dummy patterns formed separated from each other by a first spacing. The second group of dummy patterns can include a plurality of second dummy patterns formed separated from each other by the first spacing. The first dummy patterns and the second dummy patterns can have the same shape and size.

### CROSS-REFERENCE TO RELATED APPLICATION

The present application claims the benefit under 35 U.S.C. §119 of Korean Patent Application No. 10-2007-0041387, filed Apr. 27, 2007, which is hereby incorporated by reference in its entirety.

### BACKGROUND

A semiconductor device is generally formed in a multi-layer structure. Each layer of such a multi-layer structure is typically formed by means of a sputtering method, a chemical vapor deposition method, etc., and is patterned by subjecting the layer to a lithography process.

However, several problems may occur in a semiconductor device due to the differences of pattern size and pattern density, for example, on a substrate of the semiconductor device. Accordingly, technologies are being developed to form dummy patterns along with a main pattern for the device.

### BRIEF SUMMARY

An embodiment provides a semiconductor device and a method for manufacturing the same capable of securing pattern uniformity.

An embodiment provides a semiconductor device and a method for manufacturing the same incorporating a dummy pattern capable of simplifying a design process and a manufacturing process.

In an embodiment, a semiconductor device can include: a first group of dummy patterns including a plurality of first dummy patterns formed separated from each other by a first spacing; and a second group of dummy patterns formed spaced apart from the first group of dummy patterns at a second spacing, where the second group of dummy patterns include a plurality of second dummy patterns formed separated from each other by the first spacing.

In another embodiment, a semiconductor device can include: a first group of dummy patterns including a plurality of first dummy patterns separated from each other by a first spacing; a second group of dummy patterns formed spaced apart from the first group of dummy patterns at a second spacing, where the second group of dummy patterns include a plurality of second dummy patterns formed separated from each other by the first spacing each other; and a main pattern formed spaced apart from the first group of dummy patterns and/or the second group of dummy patterns by a spacing equal to or greater than the first spacing.

In yet another embodiment, a semiconductor device can include: a first group of dummy patterns including a plurality of first dummy patterns formed separated from each other by a first spacing, and a fifth dummy pattern formed spaced apart from a selected first dummy pattern by a fifth spacing; and a second group of dummy patterns formed spaced apart from the first group of dummy patterns at a second spacing, where the second group of dummy patterns include a plurality of second dummy patterns formed separated from each other by the first spacing and a sixth dummy pattern formed spaced apart from a selected second dummy pattern by a fifth spacing.

In an embodiment, a semiconductor device can include: a main pattern formed on a substrate; a plurality of dummy patterns formed having the same size in regions other than the region in which the main pattern is formed; and an interlayer dielectric layer formed on the main pattern and the plurality of dummy patterns.

A method for manufacturing a semiconductor device according to an embodiment can include: forming a main pattern on a substrate; forming a plurality of dummy patterns having the same size in regions other than the region in which the main pattern is formed; and forming an interlayer dielectric layer on the main pattern and the plurality of dummy patterns.

In an embodiment, a semiconductor device can include: a first polygonal dummy pattern having at least one side different from the remaining sides in length; and a second polygonal dummy pattern formed adjacent the first polygonal dummy pattern at a predetermined spacing from the first polygonal dummy pattern, wherein the second polygonal dummy pattern has the same size as the first polygonal dummy pattern.

### BRIEF DESCRIPTION OF THE DRAWINGS

The accompanying drawings, which are included to provide a further understanding of the invention and are incorporated in and constitute a part of this application, illustrate embodiments of the invention and together with the description serve to explain the principle of the invention. In the drawings:

FIGS. 1 to 4 are plan views showing examples of dummy patterns of a semiconductor device according to a first embodiment;

FIG. 5 is a plan view of a semiconductor device according to a second embodiment;

FIG. 6 is a cross-sectional view of a semiconductor device according to a second embodiment;

FIG. 7 is a plan view of a semiconductor device according to a third embodiment;

FIG. 8 is a plan view of a semiconductor device according to a fourth embodiment;

FIG. 9 is a cross-sectional view of a semiconductor device according to a fifth embodiment; and

FIG. 10 is a plan view of a semiconductor device according to a sixth embodiment.

### DETAILED DESCRIPTION

Reference will now be made in detail to embodiments of the present invention, examples of which are illustrated in the accompanying drawings.

Hereinafter, embodiments of a semiconductor device and a method for manufacturing the same will be described with reference to the accompanying drawings.

FIGS. 1 to 4 are plan views showing examples of dummy patterns of a semiconductor device according to a first embodiment.

In the first embodiment, a first group of dummy patterns 120 can be formed in a selected layer. The first group of dummy patterns 120 can include a plurality of first dummy patterns 122. A first dummy pattern 122 of the first group of dummy patterns 120 can be spaced apart from an adjacent first dummy pattern 122 by a first spacing A.

A second group of dummy patterns 130 can be formed in the selected layer. The second group of dummy patterns 130 can be spaced a distance from the first group of dummy patterns 120 by a second spacing B. The second group of dummy patterns 130 can include a plurality of second dummy patterns 132. A second dummy pattern 132 of the second group of dummy patterns 130 can be spaced apart from an adjacent second dummy pattern 132 by the first

In an embodiment as illustrated in FIG. 1, the first group of dummy patterns 120 can include two first dummy patterns 122 formed in a column and spaced apart from each other by the first spacing A. In addition, the second group of dummy patterns can include two second dummy patterns 132 formed in a column and spaced apart from each other by the first spacing A. The first dummy patterns 122 can align with the second dummy patterns 132 such that each first dummy pattern 122 can be spaced apart from a corresponding second dummy pattern 132 by the second spacing B. Although FIG. 1 shows an example where the first group of dummy patterns 120 and the second group of dummy pattern 130 are formed with two first dummy patterns 122 and two second dummy patterns 132, respectively, the groups are not limited thereto.

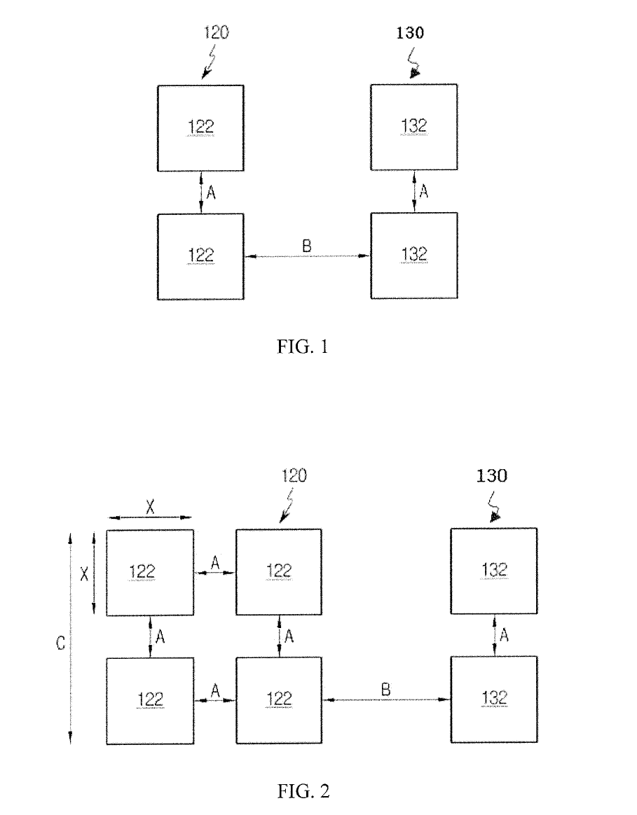

In an embodiment as illustrated in FIG. 2, the first group of dummy patterns 120 can include multiple columns of first dummy patterns 122, where each first dummy pattern 122 is spaced apart from adjacent first dummy patterns 122 by the first spacing A. In one embodiment, the first group of dummy patterns 120 can include four first dummy patterns 122 forming a quadrilateral shaped first group of dummy patterns 120 having a side length C. The second group of dummy patterns can include two second dummy patterns 132 formed in a column and spaced apart from each other by the first spacing A. The first dummy patterns 122 positioned closest to the second group of dummy patterns 130 can align with the second dummy patterns 132 such that each first dummy pattern 122 positioned closest to the second group of dummy patterns 130 can be spaced apart from a corresponding second dummy pattern 132 by the second spacing B.

In an embodiment, the first spacing A can be equal to or greater than the minimum design rule spacing between the patterns in a particular semiconductor manufacturing process.

In an embodiment, the first group of dummy patterns 120 and the second group of dummy patterns 130 can be layer patterns of a layer performing the same functions, such as, for example, an active layer pattern, a metal pattern, or a poly layer pattern.

In one embodiment, the first dummy patterns 122 and the second dummy patterns 132 can be an active layer pattern, but are not limited thereto.

In an embodiment, the first dummy patterns 122 and/or the second dummy patterns 132 can be formed in numbers of 2ⁿ (where n is an integer equal to or greater than 1).

In one embodiment, as illustrated in FIG. 1, the first dummy patterns 122 can be formed as two dummy patterns (2¹), but the embodiments are not limited thereto.

In an embodiment, the first dummy pattern 122 and the second dummy pattern 132 can have the same shape. The dummy patterns can be formed in a same shape so that the design of the dummy pattern and the speed and accuracy of the semiconductor manufacturing process can be improved and the pattern uniformity and the pattern density can be maximized.

Also, in an embodiment, the first dummy pattern 122 and the second dummy pattern 132 can have the same size. When the dummy patterns have the same shape and size, the design of the dummy pattern and the speed and accuracy of the semiconductor manufacturing process may be further improved, and the pattern uniformity and the pattern density may be maximized.

The dummy patterns can have the same shape and size so that the design of the dummy pattern and the speed and accuracy of the semiconductor manufacturing process may be improved while maximizing the pattern uniformity and the pattern density.

In an embodiment, the number of the first dummy patterns 122 and the second dummy patterns 132 can be the same as shown, for example, in FIG. 1 or different as shown, for example, in FIG. 2.

In embodiments, the first dummy pattern 122 can be a polygon. For example, the first dummy pattern 122 can be a square having a side length X, but is not limited thereto.

The first spacing A can be selected to increase the pattern density. In an embodiment, when the first dummy pattern 122 is a square, the first spacing A can be 1/16 to ¾ of the width X of the first dummy patterns 122.

In one embodiment, for example, the first spacing A between the first dummy patterns 122 can be ½ of the width X of the first dummy patterns 122, but is not limited thereto.

The width X of the first dummy patterns 122 can be equal to or greater than the minimum design rule line width or the minimum design rule width of a pattern in a particular semiconductor manufacturing process.

Also, in an embodiment, the second spacing B can be different from the first spacing A. Of course, the second spacing B can be equal to the first spacing A.

In embodiments, when the second spacing B is made to be different from the first spacing A, the second spacing B can be longer or shorter than the first spacing A.

In an embodiment when the second spacing B is longer than the first spacing A, the second spacing B can be 1 to 10 times the first spacing A. For example, the second spacing B can be 3 times the first spacing A, but is not limited thereto.

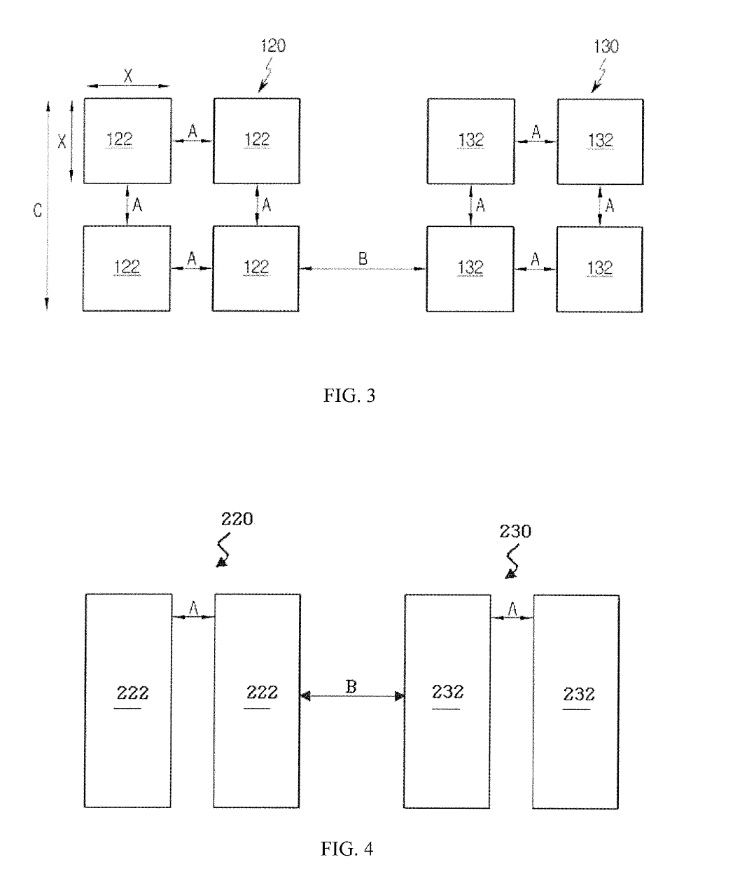

FIG. 3 shows an example embodiment where the first group of dummy patterns 120 and the second group of dummy patterns 130 are formed in the same size, shape, and pattern. In particular, FIG. 3 shows an embodiment where the first group of dummy patterns 120 and the second group of dummy patterns 130 include four first dummy patterns 122 and four second dummy patterns 132, respectively.

In such an embodiment, the dummy patterns can be arranged so that the pattern density of the dummy patterns with the same shape and size can be increased.

Next, FIG. 4 shows an embodiment utilizing another shape for a dummy pattern.

FIG. 4 shows an example of the case where the first dummy pattern 222 and the second dummy pattern 232 can be formed in the same shape and size, for example, a rectangle.

Referring to FIG. 4, in addition, the second group of dummy patterns can include two second dummy patterns 132 formed in a column and spaced apart from each other by the first spacing A. The first dummy patterns 122 can align with the second dummy patterns 132 such that each first dummy pattern 122 can be spaced apart from a corresponding second dummy pattern 132 by the second spacing B. The first group of dummy patterns 220 can include a plurality of first dummy patterns 222 formed in a row and spaced apart at a first spacing A. In addition, a second group of dummy patterns 230 can include a plurality of second dummy patterns 232 formed in a row and spaced apart from each other by the first spacing A. The second group of dummy patterns 230 can be formed at the second spacing B from the first group of dummy patterns 220.

According to embodiments, the dummy patterns with the same shape and size can be formed, making it possible to achieve pattern uniformity.

Also, according to an embodiment, a critical diameter (CD) of each pattern can be made constant by securing the pattern uniformity.

Accordingly, a semiconductor device incorporating one or more of the above described embodiments of the dummy pattern can be provided.

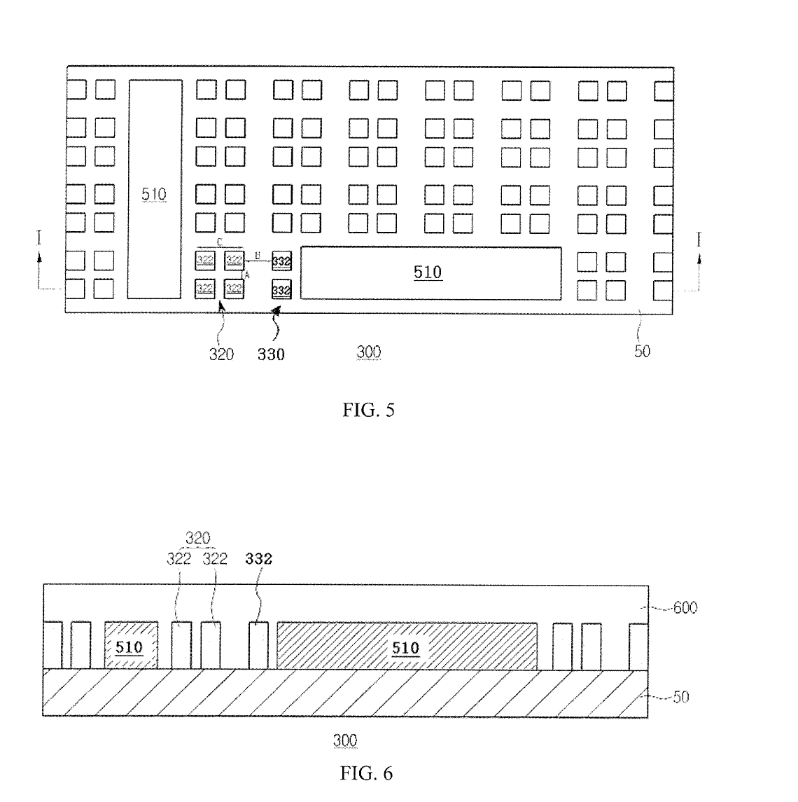

FIG. 5 is a plan view of a semiconductor device according to a second embodiment, and FIG. 6 is a cross-sectional view taken along I-I′ of FIG. 5.

The semiconductor device 300 according to an embodiment can include a main pattern 510, a first group of dummy patterns 320, and a second group of dummy patterns 330 formed on a substrate 50. The first group of dummy patterns 320 can include a plurality of first dummy patterns 322, where adjacent first dummy patterns 322 are formed spaced apart from each other at a first spacing A. The second group of dummy patterns 330 can be formed at a second spacing B from the first group of dummy patterns 320. The second group of dummy patterns 330 can include a plurality of second dummy patterns 332, where adjacent second dummy patterns 332 are formed spaced apart from each other at the first spacing A. In an embodiment, the main pattern 510 can be spaced apart from the first group of dummy patterns 320 and/or the second group of dummy patterns 330 by a distance equal to or greater than the first spacing A.

For a layer, multiple main patterns 510, multiple first groups of dummy patterns 320, and multiple second groups of dummy patterns 330 can be formed on a semiconductor substrate 50. In an embodiment, the multiple first groups 320 and the multiple second groups 330 can be formed of varying numbers of the plurality of first dummy patterns 322 and second dummy patterns 332, such that a dummy pattern does not overlap a main pattern 510 while maintaining a constant spacing for first spacing A and second spacing B.

In an embodiment, an interlayer dielectric layer pattern 600 can be formed on the main pattern 510 and the dummy patterns 320, 330 formed on a substrate 50 as shown in FIG. 6.

The second embodiment can incorporate the technical features described with respect to the embodiments of the first embodiment.

In the semiconductor device 300 of the second embodiment, the first group of dummy patterns 320 and the second group of dummy patterns 330 can be layer patterns of a layer performing the same functions.

For example, the first group of dummy patterns 320 and the second group of dummy patterns 330 can be an active layer pattern, but embodiments are not limited thereto.

In an embodiment, the first dummy patterns 322 and/or the second dummy patterns 332 can be formed in numbers of 2ⁿ (where n is an integer equal to or greater than 1). For example, as described with respect to FIG. 1, the first dummy patterns 322 can be formed as two dummy patterns (2¹), but the embodiments are limited thereto.

In an embodiment, the first dummy pattern 322 and the second dummy pattern 332 can have the same shape. The dummy patterns can be formed in a same shape so that the design of the dummy pattern and the speed and accuracy of the semiconductor manufacturing process can be improved and the pattern uniformity and the pattern density can be maximized.

Also, in an embodiment, the first dummy pattern 322 and the second dummy pattern 332 can have the same size. When the dummy patterns have the same shape and size, the design of the dummy pattern and the speed and accuracy of the semiconductor manufacturing process may be further improved, and the pattern uniformity and the pattern density can be maximized.

The dummy patterns can have the same shape and size so that the design of the dummy pattern and the speed and accuracy of the semiconductor manufacturing process may be improved while maximizing the pattern uniformity and the pattern density.

In an embodiment, the number of the first dummy patterns 322 and the second dummy patterns 332 can be the same or different.

In embodiments, the first dummy pattern 322 can be a polygon. For example, the first dummy pattern 322 may be a square, but is not limited thereto.

In an embodiment, when the first dummy pattern 322 is a square, the first spacing A can be 1/16 to ¾ of the width of the first dummy patterns 322.

In an embodiment, the second spacing B can be different from the first spacing A. Of course, the second spacing B can be equal to the first spacing A.

In embodiments where the second spacing B is made to be longer than the first spacing A, the second spacing B can be 1 to 10 times the first spacing A. For example, the second spacing B can be 3 times the first spacing A, but is not limited thereto.

With a semiconductor device according to the second embodiment, the dummy patterns with the same shape and size can be formed, making it possible to achieve pattern uniformity.

Also, according to an embodiment, a critical diameter (CD) of each pattern can be made constant by securing the pattern uniformity.

Accordingly, a semiconductor device incorporating one or more of the above described embodiments of the dummy pattern can be provided.

Meanwhile, in the semiconductor device 300 according to the second embodiment a main pattern 510 can be formed along with the first group of dummy patterns 320 and the second group of dummy patterns 330.

The dummy pattern and the main pattern can be simultaneously formed. Therefore, the reduction of data amount and the speed and accuracy of the semiconductor manufacturing process may be improved.

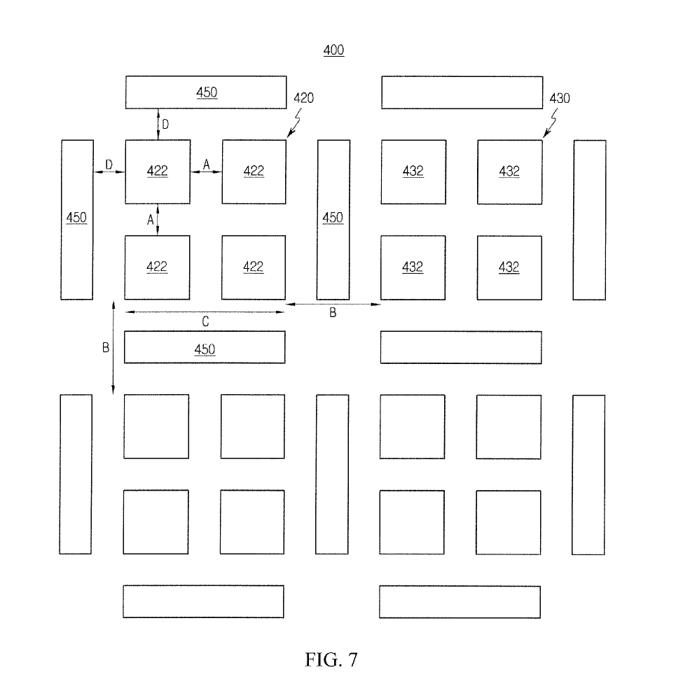

FIG. 7 is a plan view of a semiconductor device 400 according to a third embodiment.

A semiconductor device 400 according to an embodiment can include a first group of dummy patterns 420 and a second group of dummy patterns spaced apart from the first group of dummy patterns 420 by a second spacing B. The first group of dummy patterns 420 can include a plurality of first dummy patterns 422, where adjacent first dummy patterns 422 are formed spaced apart by a first spacing A. The second group of dummy patterns 430 can include a plurality of second dummy patterns 432, where adjacent second dummy patterns 432 are formed spaced apart by the first spacing A. In this embodiment, the second spacing B is larger than the first spacing A.

In a further embodiment, third dummy patterns 450 can be formed between the first group of dummy patterns 420 and the second group of dummy patterns 430.

The third dummy patterns 450 can be spaced apart from the first group of dummy patterns 420 and the second group of dummy patterns 430 by a third spacing D. The third spacing D can be equal to or greater than the minimum design rule line width for a particular semiconductor manufacturing process.

The third embodiment can incorporate the technical features described with respect to the embodiments of the second embodiment.

In the semiconductor device 400 according to the third embodiment, the first group of dummy patterns 420 and the second group of dummy patterns 430 can be layer patterns of a layer performing the same functions. The third dummy patterns 450 can be formed in a different layer from the first group of dummy patterns 420 and the second group of dummy patterns 430.

For example, the first group of dummy pattern 420 and the second group of dummy pattern 430 can be an active layer pattern, and the third dummy pattern 450 can be a poly layer pattern, but embodiments are not limited thereto.

The semiconductor device 400 according to the third embodiment can be formed with a main pattern (not shown).

The dummy patterns and the main patterns can be simultaneously formed. The dummy patterns can be formed of a same shape and size so that the reduction of data amount and the speed and accuracy of the semiconductor manufacturing process can be improved.

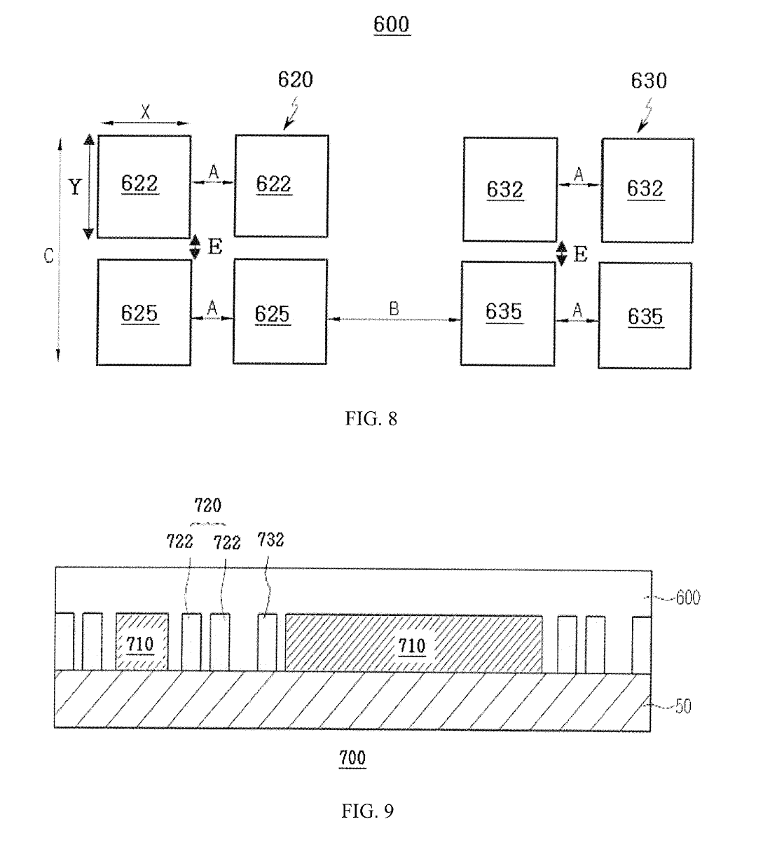

FIG. 8 is a plan view of a semiconductor device 600 according to a fourth embodiment.

The fourth embodiment can include a first group of dummy patterns 620 and a second group of dummy patterns 630. The first group of dummy patterns 620 can include a plurality of first dummy patterns 622 and a fifth dummy pattern 625. The fifth dummy pattern 625 can be formed at a fifth spacing E from a first dummy pattern 622. The second group of dummy patterns 630 can be formed at a second spacing B from the first group of dummy patterns 620. The second group of dummy patterns 630 can include a plurality of second dummy patterns 632 and a sixth dummy pattern 635. The sixth dummy pattern can be formed at the fifth spacing E from a second dummy pattern 632.

FIG. 8 shows an example where the first group of dummy patterns 620 and the second group of dummy patterns 630 include four dummy patterns, respectively, but embodiments are not limited thereto. In an embodiment, adjacent first dummy patterns 622 can be spaced apart by a first spacing A and adjacent fifth dummy patterns 625 can be spaced apart by the first spacing A, such that the spacing between a row of first dummy patterns 622 and a row of fifth dummy patterns 625 can be different than the spacing between columns of dummy patterns in the first group of dummy patterns 620. The spacings between second dummy patterns 632 and sixth dummy patterns 635 can be the same as the spacings between the first dummy 622 patterns and the fifth dummy patterns 625.

The fourth embodiment may be characterized in that the dummy patterns of a group of dummy patterns can have different spacings between adjacent dummy patterns within a group of dummy patterns.

That is, in an embodiment, the first group of dummy patterns 620 can include a plurality of first dummy patterns 622 formed spaced apart from each other by the first spacing A and a fifth dummy pattern 625 can be formed spaced apart from a first dummy pattern 622 by a fifth spacing E.

The first spacing A and the fifth spacing E can be equal to or greater than the minimum design rule spacing between patterns in a particular semiconductor manufacturing process.

At this time, in an embodiment, the first spacing A can be longer than the fifth spacing E; however, embodiments are not limited thereto. That is, the first spacing A can be shorter than the fifth spacing E.

The fourth embodiment can incorporate the technical features described with respect to embodiments of the first, second, and third embodiments.

That is, in the fourth embodiment, the first group of dummy patterns 620 and the second group of dummy patterns 630 can be layer patterns of a layer performing the same functions, such as, for example, an active layer pattern, a metal pattern, or a poly layer pattern.

In an embodiment, the first dummy patterns 622 and/or the second dummy patterns 632 can be formed in 2ⁿ (where n is an integer equal to or greater than 1).

In an embodiment, the first dummy pattern 622, the fifth dummy pattern 625, the second dummy pattern 632, and the sixth dummy pattern 635 can have the same shape. The dummy patterns can be formed in a same shape and size so that the design of the dummy pattern and the speed and accuracy of the semiconductor manufacturing process can be improved, and the pattern uniformity and the pattern density can be maximized.

In one embodiment, the dummy patterns can be formed in the shape of a rectangle. When a dummy pattern is a rectangle, the horizontal width X and vertical width V of the dummy pattern are different from each other. Therefore, the horizontal width X may be longer or shorter than the vertical width Y.

The width of the dummy patterns can be equal to or greater than the minimum design rule line width or the minimum design rule width of a pattern in a particular semiconductor manufacturing process.

FIG. 9 is a plan view of a semiconductor device 700 according to a fifth embodiment.

Referring to FIG. 9, a semiconductor device can include a main pattern 710 formed on a substrate 50; a plurality of dummy patterns 722 and 732 formed at the same size in regions other than a region in which the main pattern 710 is formed; and an interlayer dielectric layer 600 formed on the main pattern and the plurality of dummy patterns 722 and 732.

The semiconductor device according to the fifth embodiment can incorporate the features described with respect to embodiments of the first to fourth embodiments.

For example, in an embodiment, the dummy patterns can include: a first group of dummy patterns 720 and a second group of dummy patterns spaced apart from the first group of dummy patterns 720 by a second spacing B. The first group of dummy patterns can include a plurality of first dummy patterns 722 formed spaced apart from each other by a first spacing A; The second group of dummy patterns can include a plurality of second dummy patterns 732 formed spaced apart from each other at the first spacing A.

In a semiconductor device according to the fifth embodiment, the first dummy patterns 722 and the second dummy patterns 732 can have the same shape.

Also, in an embodiment, the dummy patterns can include a first group of dummy patterns 720 and a second group of dummy patterns spaced apart from the first group of dummy patterns 720 by a second spacing B. The first group of dummy patterns 720 can include a plurality of first dummy patterns 723 formed spaced apart from each other by a first spacing and a fifth dummy pattern (not shown) formed spaced apart from a first dummy pattern 723 by a fifth spacing E. The second group of dummy patterns can include a plurality of second dummy patterns 732 formed spaced apart from each other by the first spacing and a sixth dummy pattern spaced apart from a second dummy pattern 732 by the fifth spacing E.

In an embodiment, the first spacing can be different from the fifth spacing.

A method for manufacturing a semiconductor device according to an embodiment can include: forming a main pattern on a substrate; forming a plurality of dummy patterns with the same size in regions other than a region in which the main pattern is formed; and forming an interlayer dielectric layer on the main pattern and the plurality of dummy patterns.

The method for manufacturing the semiconductor device according to the fifth embodiment can incorporate the features described with respect to embodiments of the first to fourth embodiments.

For example, forming the dummy patterns can include forming a first group of dummy patterns including a plurality of first dummy patterns separated from each other by a first spacing; and forming a second group of dummy patterns separated by a second spacing from the first group of dummy patterns, where the second group of dummy patterns include a plurality of second dummy patterns separated from each other by the first spacing.

In another embodiment, forming the dummy patterns can include forming a first group of dummy patterns including a plurality of first dummy patterns separated from each other by a first spacing and a fifth dummy pattern spaced apart from a first dummy pattern by a fifth spacing; forming a second group of dummy pattern separated by a second spacing from the first group of dummy patterns, where the second group of dummy patterns include a plurality of second dummy patterns separated from each other by the first spacing and a sixth dummy pattern spaced apart from a second dummy pattern by the fifth spacing.

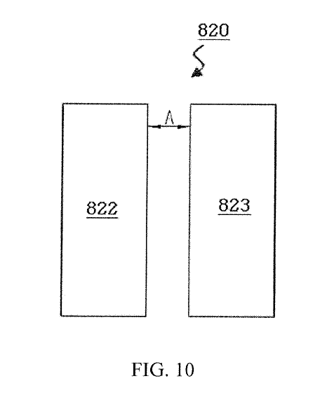

FIG. 10 is a plan view of a semiconductor device according to a sixth embodiment.

The semiconductor device according to an embodiment can include a first group of dummy patterns 820 that can include a first dummy pattern 822 having a polygonal shape where at least one side length is different from the remaining side lengths; and a second dummy pattern 823 having a polygonal shape formed at a predetermined spacing A from the first dummy pattern 822, and having the same size as the first dummy pattern 822.

The semiconductor device according to the sixth embodiment can incorporate the technical features described with respect to embodiments of the first to fourth embodiments.

For example, the dummy patterns 822 and 823 can have the same shape.

Also, in a further embodiment, a second group of dummy patterns (not shown) including dummy patterns with the same shape and size as the first group of dummy patterns 820 can be included.

As described above, according to embodiments, dummy patterns with the same shape and size can be formed, making it possible to achieve pattern uniformity.

Also, according to embodiments, a critical diameter (CD) of each pattern can be made constant by securing the pattern uniformity.

Accordingly, a semiconductor device incorporating one or more of the above described embodiments utilizing dummy patterns with the same shape and size can be provided.

In embodiments, a semiconductor device incorporating one or more of the above described embodiments utilizing dummy patterns with the same shape and size may be capable of simplifying the design and manufacturing processes.

In embodiments, dummy patterns having the same shape and size can be provided for a layer without the need for second dummy patterns for that layer of a different shape and/or size.

With reference to the description of the embodiments, in the case described as what is formed “on/under” each layer, the “on/under” covers all the “what is directly formed” or “what is formed by interposing (indirectly) other layer therebetween.”

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A semiconductor device comprising:
a first group of dummy patterns, the first group of dummy patterns comprising at least one first dummy pattern, wherein adjacent first dummy patterns are separated from each other by a first spacing; and
a second group of dummy patterns, the second group of dummy patterns comprising at least two second dummy patterns, wherein adjacent second dummy patterns are separated from each other by the first spacing,
wherein the second group of dummy patterns are spaced apart from the first group of dummy patterns by a second spacing.

2. The device according to claim 1, wherein the first dummy patterns and the second dummy patterns have the same shape.

3. The device according to claim 1, wherein the first dummy patterns and the second dummy patterns have the same size.

4. The device according to claim 1, wherein the second spacing is longer than the first spacing.

5. The device according to claim 1, wherein the second spacing is shorter than the first spacing.

6. The device according to claim 1, wherein the first dummy pattern is a polygon.

7. The device according to claim 1, further comprising a main pattern formed of the same layer as the first dummy patterns and the second dummy patterns.

8. The device according to claim 7, further comprising an interlayer dielectric layer on the main pattern, the first dummy patterns, and the second dummy patterns.

9. The device according to claim 7, wherein the main pattern is separated from the first group of dummy patterns and/or the second group of dummy patterns by a distance equal to or greater than the first spacing.

10. The device according to claim 7, further comprising third dummy patterns formed on a different layer between the first group of dummy patterns and the second group of dummy patterns.

11. The device according to claim 1, further comprising third dummy patterns formed on a different layer between the first group of dummy patterns and the second group of dummy patterns.

12. The device according to claim 1, wherein the first group of dummy patterns further comprises a fifth dummy pattern separated from a selected first dummy pattern by a fifth spacing; and
wherein the second group of dummy patterns further comprises a sixth dummy pattern separated from a selected second dummy pattern by the fifth spacing.

13. The device according to claim 12, wherein the first spacing, the second spacing, and the fifth spacing are different in size.

14. The device according to claim 12, wherein the first dummy patterns, the fifth dummy pattern, the second dummy patterns, and the sixth dummy pattern have the same shape and size.

15. A semiconductor device comprising:
a main pattern formed on a substrate;
a plurality of dummy patterns formed of the same size in regions other than a region in which the main pattern is formed, wherein the plurality of dummy patterns comprise:
a first group of dummy patterns including a plurality of first dummy patterns separated from each other by a first spacing, and
at least one second dummy pattern formed separated from the first group of dummy patterns by a second spacing different from the first spacing; and
an interlayer dielectric layer formed on the main pattern and the plurality of dummy patterns.

16. The device according to claim 15, wherein each dummy pattern of the plurality of dummy patterns has the same shape.

17. A method for manufacturing a semiconductor device comprising:
forming a main pattern on a substrate; and
forming a plurality of dummy patterns in regions other than a region in which the main pattern is formed, wherein each dummy pattern in the plurality of dummy patterns has the same size.

18. The method according to claim 17, further comprising:
forming an interlayer dielectric layer on the main pattern and the plurality of dummy patterns.

19. The method according to claim 17, wherein forming the plurality of dummy patterns comprises:
forming a first group of dummy patterns including a plurality of first dummy patterns separated from each other by a first spacing; and
forming a second group of dummy patterns spaced apart from the first group of dummy patterns by a second spacing different from the first spacing, wherein the second group of dummy patterns comprises at least one second dummy pattern.

20. The method according to claim 17, wherein the main pattern and the plurality of dummy patterns are simultaneously formed.
